(19) United States
(12) Patent Application Publication
(10) Pub. No.: US 2020/0381272 A1
(43) Pub. Date: Dec. 3, 2020

(54) PLACING TABLE STRUCTURE AND TREATMENT DEVICE

(71) Applicant: Tokyo Electron Limited, Tokyo (JP)

(72) Inventors: Shinji ORIMOTO, Tokyo (JP); Manabu NAKAGAWASAI, Tokyo (JP); Kouji MAEDA, Yamanashi (JP); Hiroshi MIKI, Tokyo (JP); Naoyuki SUZUKI, Yamanashi (JP)

(21) Appl. No.: 16/624,492

(22) PCT Filed: Jun. 25, 2018
(86) PCT No.: PCT/JP2018/023967

§ 371 Date: Dec. 19, 2019

(30) Foreign Application Priority Data
Jul. 7, 2017 (JP) 2017-133991
Mar. 6, 2018 (JP) 2018-039397

(51) Int. Cl. H01L 21/67; H01L 21/683; H01L 21/687

(52) U.S. Cl. CPC H01L 21/67109; H01L 21/68742; H01L 21/6833

(57) ABSTRACT

A placing table structure according to an embodiment includes: a fixedly disposed refrigerated heat transfer element; a rotatable outer cylinder disposed around the refrigerated heat transfer element; and a stage connected to the outer cylinder and disposed above an upper surface of the refrigerated heat transfer element with inclusion of a gap between the refrigerated heat transfer element and the stage.

### TECHNICAL FIELD

The present invention generally relates to a placing table structure and a treatment device.

### BACKGROUND

Conventionally, it is known that a magnetoresistance element having a high magnetoresistance ratio can be manufactured by using a magnetic film formed under a very high vacuum and extremely low temperature environment. As a method of forming a magnetic film under a very high vacuum and extremely low temperature environment, there is a method in which a magnetic film is formed on an object that has been cooled to an extremely low temperature by a cooling device, by using a film forming device different from the cooling device.

As a cooling device, a configuration having an electrostatic attracting device that can be used in an extremely low temperature environment is known (see Patent Document 1, for example).

### CITATION LIST

### [Patent Document]

### [Patent Document 1] Japanese Laid-open Patent Application Publication No. 2015-226010

### SUMMARY

### Problem to be Solved by the Invention

When cooling and film forming are performed in different devices, it is difficult to maintain a temperature of an object to be processed at an extremely low temperature when forming a magnetic film, and it is difficult to manufacture a magnetoresistance element having a high magnetoresistance ratio.

Alternatively, a method in which a magnetic film is formed on an object under a very high vacuum and extremely low temperature environment in the same device may be considered, by providing a film forming mechanism to the aforementioned cooling device. However, because an electrostatic chuck is not rotatable in the aforementioned cooling device, it is difficult to obtain good in-plane uniformity.

It is an object of the present invention to provide a placing table structure capable of rotating an object while maintaining an extremely low temperature.

### Means for Solving Problem

In order to achieve the above-described object, a placing table structure according to one aspect of the present invention includes a fixedly disposed refrigerated heat transfer element, a rotatable outer cylinder disposed around the refrigerated heat transfer element, and a stage connected to the outer cylinder and disposed above an upper surface of the refrigerated heat transfer element with inclusion of a gap between the refrigerated heat transfer element and the stage.

### Effect of Invention

According to the placing table structure in the present disclosure, an object can be rotated while the object is maintained at an extremely low temperature.

### BRIEF DESCRIPTION OF THE DRAWINGS

FIG. 1 is a schematic cross-sectional view illustrating an example of a treatment device according to a first embodiment of the present invention;

FIG. 2 is an example of a gap in the placing table structure of the treatment device illustrated in FIG. 1;

FIG. 3 is a schematic cross-sectional view illustrating an example of a treatment device according to a second embodiment of the present invention; and

FIG. 4 is a schematic cross-sectional view illustrating an example of a treatment device according to a third embodiment of the present invention.

### DESCRIPTION OF EMBODIMENTS

In the following, embodiments of the present invention will be described with reference to the drawings. Note that in the following descriptions and the drawings, elements having substantially identical features are given the same reference symbols and overlapping descriptions may be omitted.

### First Embodiment

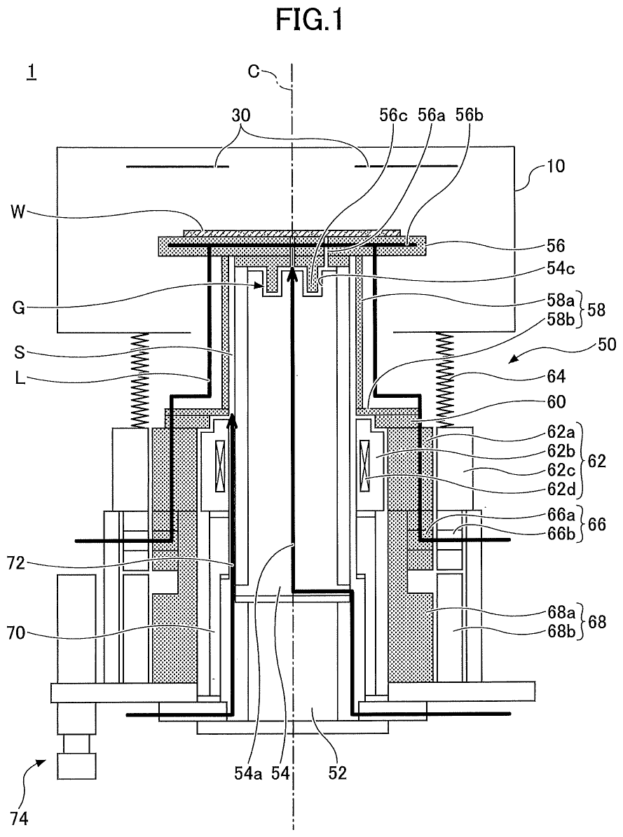

A treatment device having a placing table structure according to a first embodiment of the present invention will be described. FIG. 1 is a schematic cross-sectional view illustrating an example of the treatment device according to the first embodiment of the present invention.

As illustrated in FIG. 1, the treatment device 1 is a film-forming apparatus capable of forming a magnetic film on a semiconductor wafer W that is an object of processing, in a vacuum vessel 10 configured to be processed under a very high vacuum and extremely low temperature environment. The magnetic film is used, for example, in Tunneling Magneto Resistance (TMR) elements. The treatment device 1 includes the vacuum vessel 10, a target 30, and a placing table structure 50.

The interior of the vacuum vessel 10 is capable of being depressurized to a very high vacuum (e.g., 10⁻⁵ Pa or less). A gas supply line (not illustrated) is externally connected to the vacuum vessel 10, to supply gas (e.g., rare gases such as argon, krypton, and neon, and nitrogen gas) required for a sputtering film forming process. In addition, the vacuum vessel 10 is connected to an exhaust means (not illustrated) such as a vacuum pump, which is capable of evacuating gases or the like supplied from the gas supply line and which is capable of reducing pressure in the vacuum vessel 10 to a very high vacuum.

The target 30 is disposed above the placing table structure 50 and within the vacuum vessel 10. To the target 30, AC (Alternating Current) voltage is applied from a power supply for plasma generation (not illustrated). When the AC voltage is applied to the target 30 from the power supply for plasma generation, a plasma is generated in the vacuum vessel 10, to ionize a rare gas or the like in the vacuum vessel 10 and to sputter the target 30 with ionized rare gas elements or the like. Atoms or molecules of the sputtered target material are deposited on a surface of the semiconductor wafer W that faces the target 30 and that is held by the placing table structure 50. Although the number of targets 30 is not particularly limited, it is preferable to have multiple targets 30, in terms of ability to deposit different materials in the single treatment device 1. For example, when a magnetic film (a film containing a ferromagnetic material such as Ni, Fe, or Co) is deposited, CoFe, FeNi, or NiFeCo may be used as a material of the target 30. Additional elements may also be contained in the target 30 materials.

The placing table structure 50 includes a refrigerator 52, a refrigerated heat transfer element 54, a stage 56, and an outer cylinder 58.

The refrigerator 52 holds the refrigerated heat transfer element 54, and cools an upper surface of the refrigerated heat transfer element 54 to an extremely low temperature (e.g., −30° C. or less). The refrigerator 52 preferably utilizes the GM (Gifford-McMahon) cycle in terms of cooling capacity.

The refrigerated heat transfer element 54 is fixed on the refrigerator 52, and an upper portion of the refrigerated heat transfer element 54 is disposed in the vacuum vessel 10. The refrigerated heat transfer element 54 is formed of a highly thermally conductive material, such as pure copper (Cu), and is of substantially cylindrical shape. The refrigerated heat transfer element 54 is disposed such that the center of the refrigerated heat transfer element 54 is aligned with a central axis C of the stage 56. Inside the refrigerated heat transfer element 54, a first cooling gas supply section 54a is formed, which communicates with a gap G to be described below, and allows a first cooling gas to flow. Accordingly, the first cooling gas can be supplied to the gap G. As the first cooling gas, it is preferable to use helium (He) in terms of high thermal conductivity.

The stage 56 is disposed above the refrigerated heat transfer element 54, with the gap G (such as 2 mm or less) between the stage 56 and the upper surface of the refrigerated heat transfer element 54. The stage 56 is formed of a highly thermally conductive material such as pure copper (Cu). The gap G communicates with the first cooling gas supply section 54a formed in the refrigerated heat transfer element 54. Accordingly, the first cooling gas is supplied to the gap G from the first cooling gas supply section 54a. Thus, the stage 56 is cooled to an extremely low temperature (e.g., below −30° C.) by the refrigerator 52, the refrigerated heat transfer element 54, and the first cooling gas supplied to the gap G. Instead of the first cooling gas, the gap G may be filled with heat conductive grease having good thermal conductivity. In this case, because the first cooling gas supply section 54a is not required, a structure of the refrigerated heat transfer element 54 can be simplified. In the stage 56, a through hole 56a that penetrates the upper and lower surfaces of the stage 56 is formed. The through hole 56a communicates with the first cooling gas supply section 54a through the gap G. Accordingly, a part of the first cooling gas, which is supplied from the first cooling gas supply section 54a to the gap G, is fed between an upper surface of the stage 56 (electrostatic chuck) and a lower surface of the semiconductor wafer W through the through hole 56a. Therefore, cryogenic heat of the refrigerated heat transfer element 54 is efficiently transferred to the semiconductor wafer W. The number of the through holes 56a may be one or more. However, it is preferable that the multiple through holes 56a are provided in order to transmit cryogenic heat of the refrigerated heat transfer element 54 to the semiconductor wafer W efficiently. The stage 56 includes the electrostatic chuck. The electrostatic chuck includes a chuck electrode 56b embedded in a dielectric film. An electric potential of a predetermined magnitude is applied to the chuck electrode 56b via wiring L. This allows the semiconductor wafer W to be attracted and fixed to the electrostatic chuck.

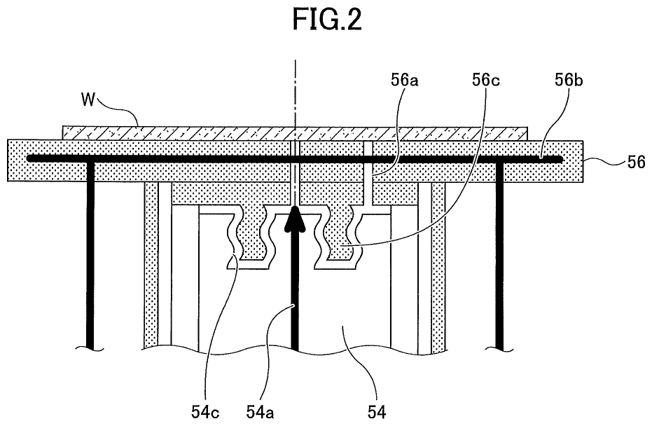

On the lower surface of the stage 56, a protrusion 56c protruding toward the refrigerated heat transfer element 54 is formed. In an example illustrated in the drawings, the protrusion 56c is of substantially annular shape, which surrounds the central axis C of the stage 56. A height of the protrusion 56c may be, for example, 40 to 50 mm. A width of the protrusion 56c may be, for example, 6 to 7 mm. Although the shape and the number of the protrusions 56c are not particularly limited, it is preferable that the shape and the number of the protrusion 56c are determined so as to increase a surface area of the protrusion 56c, from a viewpoint of increasing the heat transfer efficiency between the protrusions 56c and the refrigerated heat transfer element 54. The protrusion 56c may have, for example, a corrugated shape on an outer surface of the protrusion 56c, as illustrated in FIG. 2. Further, it is preferable that the outer surface of the protrusion 56c is subjected to a roughening process such as abrasive blasting. This is because the surface area can be increased to increase heat transfer efficiency between the refrigerated heat transfer element 54 and the protrusion 56c. Further, the multiple protrusions 56c may be formed.

A portion of the stage 56 including the electrostatic chuck and a portion of the stage 56 including the protrusion 56c may be formed integrally, or may be formed separately and bonded.

The upper surface of the refrigerated heat transfer element 54, that is, the surface facing the protrusion 56c, is formed with a recess 54c fitted to the protrusion 56c with the gap G. In the illustrated example, the recess 54c is of substantially annular shape, which surrounds the central axis C of the stage 56. A height of the recess 54c may be the same as the height of the protrusion 56c, which is for example, between 40 mm and 50 mm. A width of the recess 54c may be, for example, slightly wider than the width of the protrusion 56c, which is preferably 7 to 9 mm, for example. The shape and the number of the recesses 54c are defined so as to correspond to the shape and the number of the protrusions 56c. For example, if the outer surface of the protrusion 56c is of corrugated shape as illustrated in FIG. 2, an inner surface of the recess 54c may also be of corrugated shape. Further, it is preferable that the inner surface of the recess 54c is subjected to a roughening process such as abrasive blasting. This is because the surface area can be increased to increase heat transfer efficiency to the stage 56. Also, the multiple recesses 54c may be formed.

The outer cylinder 58 is disposed around the refrigerated heat transfer element 54. In the illustrated example, the outer cylinder 58 is disposed to cover an outer peripheral surface of the upper portion of the refrigerated heat transfer element 54. The outer cylinder 58 has a cylindrical portion 58a having an inner diameter slightly larger than an outer diameter of the refrigerated heat transfer element 54, and a flange portion 58b which extends in an outer radial direction at a position of the lower surface of the cylindrical portion 58a. The cylindrical portion 58a and the flange portion 58b are formed of metal such as stainless steel. A heat insulating member 60 is connected to the lower surface of the flange portion 58b.

The heat insulating member 60 is of substantially cylindrical shape, and extends coaxially with the flange portion 58b. The heat insulating member 60 is fixed to the flange portion 58b. The heat insulating member 60 is formed of a ceramic such as alumina. A magnetic fluid seal section 62 is provided on the lower surface of the heat insulating member 60.

The magnetic fluid seal section 62 includes a rotating member 62a, an inner stationary member 62b, an outer stationary member 62c, and a heating means 62d. The rotating member 62a is of substantially cylindrical shape, and extends coaxially with the heat insulating member 60. The rotating member 62a is fixed to the heat insulating member 60. In other words, the rotating member 62a is connected to the outer cylinder 58 via the heat insulating member 60. Accordingly, because cryogenic heat transfer from the outer cylinder 58 to the rotating member 62a is blocked by the heat insulating member 60, it is possible to avoid degradation of sealing performance of the magnetic fluid seal section 62 or occurrence of condensation on the magnetic fluid seal section 62, which is caused by temperature decrease of the magnetic fluid of the magnetic fluid seal section 62. The inner stationary member 62b is provided between the refrigerated heat transfer element 54 and the rotating member 62a via magnetic fluid. The inner stationary member 62b is of substantially cylindrical shape. An inner diameter of the inner stationary member 62b is greater than an outer diameter of the refrigerated heat transfer element 54, and an outer diameter of the inner stationary member 62b is smaller than an inner diameter of the rotating member 62a. The outer stationary member 62c is provided on the outside of the rotating member 62a via magnetic fluid. The outer stationary member 62c is of substantially cylindrical shape, and has an inner diameter greater than an outer diameter of the rotating member 62a. The heating means 62d is embedded in the inner stationary member 62b to heat an entirety of the magnetic fluid seal section 62. Accordingly, it is possible to avoid degradation of sealing performance of the magnetic fluid seal section 62 or occurrence of condensation on the magnetic fluid seal section 62, which is caused by temperature decrease of the magnetic fluid of the magnetic fluid seal section 62. Due to the above-described configuration, in the magnetic fluid seal section 62, the rotating member 62a is rotatable in an airtight condition with respect to the inner stationary member 62b and the outer stationary member 62c. That is, the outer cylinder 58 is supported via the magnetic fluid seal section 62 in a rotatable manner. A bellows 64 is provided between the upper surface of the outer stationary member 62c and the bottom surface of the vacuum vessel 10.

The bellows 64 is a metal bellows structure that can be stretched and contracted upward and downward. The bellows 64 surrounds the refrigerated heat transfer element 54, the outer cylinder 58, and the heat insulating member 60, to separate a space in the vacuum vessel 10 capable of being depressurized from a space outside the vacuum vessel 10.

A slip ring 66 is provided under the magnetic fluid seal section 62. The slip ring 66 has a rotor 66a including a metal ring, and a stator 66b including a brush. The rotor 66a is of substantially cylindrical shape, and extends coaxially with the rotating member 62a of the magnetic fluid seal section 62. The rotor 66a is fixed to the rotating member 62a. The stator 66b is of substantially cylindrical shape, and has an inner diameter slightly greater than an outer diameter of the rotor 66a. The slip ring 66 is electrically connected to a DC (Direct Current) power supply (not illustrated), and transmits power supplied from the DC power supply to the wiring L via the brush of the stator 66b and the metal ring of the rotor 66a. According to the configuration described above, an electric potential can be applied from the DC power supply to the chuck electrode without the wiring L being twisted. The rotor 66a of the slip ring 66 is attached to a drive mechanism 68.

The drive mechanism 68 is a direct drive motor having a rotor 68a and a stator 68b. The rotor 68a is of substantially cylindrical shape, and extends coaxially with the rotor 66a of the slip ring 66. The rotor 68a is fixed to the rotor 66a. The stator 68b is of substantially cylindrical shape, and has an inner diameter greater than an outer diameter of the rotor 68a. According to the configuration described above, when the rotor 68a rotates, the rotor 66a, the rotating member 62a, the outer cylinder 58, and the stage 56 rotate with respect to the refrigerated heat transfer element 54.

The refrigerator 52 and the refrigerated heat transfer element 54 are surrounded by a heat insulator 70 of a vacuum heat-insulating double-walled structure. In the illustrated example, the heat insulator 70 is provided between the refrigerator 52 and the rotor 68a and between the lower portion of the refrigerated heat transfer element 54 and the rotor 68a. This prevents cryogenic heat of the refrigerator 52 and cryogenic heat of the refrigerated heat transfer element 54 from being transferred to the rotor 68a.

Also, around the refrigerator 52 and the refrigerated heat transfer element 54, a second cooling gas supply section 72 is formed. The second cooling gas supply section 72 supplies a second cooling gas to a space S between the refrigerated heat transfer element 54 and the outer cylinder 58. Because thermal conductivity of the second cooling gas is different from, for example, that of the first cooling gas, and is preferably lower than that of the first cooling gas, a temperature of the second cooling gas becomes relatively higher than that of the first cooling gas. The second cooling gas can prevent the first cooling gas leaked from the gap G into the space S from entering the magnetic fluid seal section 62. In other words, the second cooling gas functions as a counterflow to the first cooling gas leaking from the gap G. Accordingly, it is possible to avoid degradation of sealing performance of the magnetic fluid seal section 62 or occurrence of condensation on the magnetic fluid seal section 62, which is caused by temperature decrease of the magnetic fluid of the magnetic fluid seal section 62. In order to enhance the function as a counterflow, it is preferable that supply pressure of the second cooling gas is substantially the same as or slightly higher than that of the first cooling gas. As the second cooling gas, a low boiling point gas such as argon or neon may be used.

A temperature sensor for detecting a temperature of the refrigerated heat transfer element 54, the gap G, or the like may be provided. As the temperature sensor, a temperature sensor for low temperature, such as a silicon diode temperature sensor or a platinum resistance temperature sensor, may be used.

The treatment device 1 also includes a lifting mechanism 74 for raising and lowering the entire placing table structure 50 relative to the vacuum vessel 10. This allows a distance between the target 30 and the semiconductor wafer W to be controlled. Specifically, by raising and lowering the placing table structure 50 using the lifting mechanism 74, a position when the semiconductor wafer W is placed on the stage 56 can be made to be different from a position when a film is deposited onto the semiconductor wafer W placed on the stage 56.

As described above, the placing table structure 50 of the first embodiment includes the fixedly disposed refrigerated heat transfer element 54, the rotatable outer cylinder 58 disposed around the refrigerated heat transfer element 54, and the stage 56 connected to the outer cylinder 58 and disposed with the gap G with respect to the upper surface of the refrigerated heat transfer element 54. This allows the semiconductor wafer W to rotate at an extremely low temperature. Further, by using the treatment device 1 including the placing table structure 50, a magnetoresistance element having good in-plane uniformity and a high magnetoresistance ratio can be manufactured.

In particular, in a case in which film deposition is performed in the treatment device 1 in which multiple targets 30 of different materials are disposed above the stage 56, by using the placing table structure 50 according to the first embodiment of the present invention in which the stage 56 rotates, excellent in-plane uniformity can be realized. On the other hand, if the stage 56 does not rotate, it is difficult to achieve excellent in-plane uniformity because a distance from a target 30 to the upper surface of the semiconductor wafer W differs in each target 30. For example, a case in which film thickness or film quality differs may occur.

### Second Embodiment

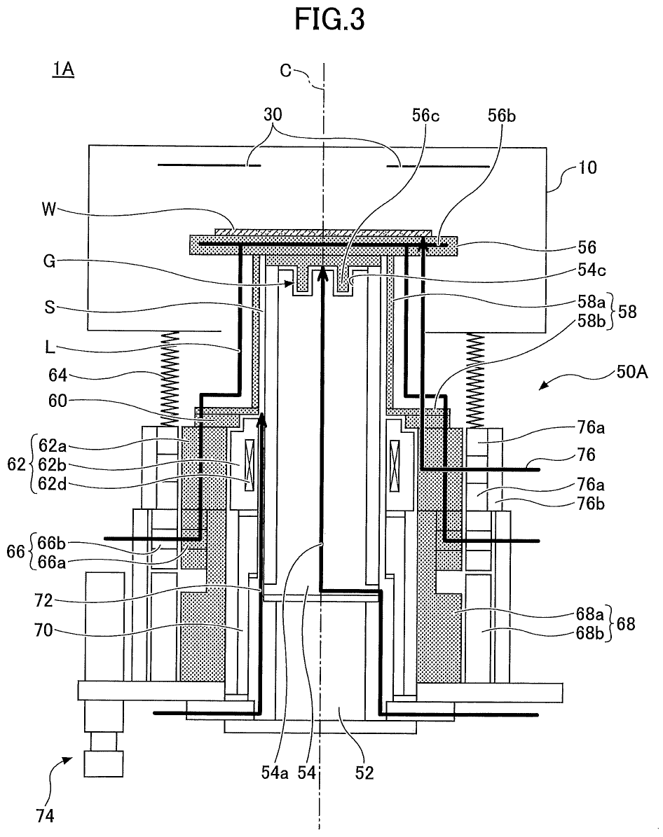

A treatment device having a placing table structure according to a second embodiment of the present invention will be described. In the second embodiment, instead of the through hole 56a of the placing table structure 50 of the first embodiment, a third cooling gas supply section 76 is formed. Hereinafter, points different from the first embodiment will be mainly described. FIG. 3 is a schematic cross-sectional view illustrating an example of the treatment device according to the second embodiment of the present invention.

By the third cooling gas supply section 76, a third cooling gas is supplied between the upper surface of the stage 56 and the lower surface of the semiconductor wafer W. As the third cooling gas, for example, helium may be used, which is similar to the first cooling gas. The third cooling gas supply section 76 is introduced into a placing table structure 50A, via a magnetic fluid seal section 76a for example. A cover 76b is provided on an outer circumference of the magnetic fluid seal section 76a.

According to the above-described placing table structure 50A of the second embodiment, in addition to the aforementioned effects of the first embodiment, the following effects are achieved.

In the treatment device 1 having the placing table structure 50 according to the aforementioned first embodiment, if the stage 56 is cooled without the semiconductor wafer W being placed, the first cooling gas is vigorously discharged into the vacuum vessel 10 maintained in high vacuum quality, and heat transfer in the gap G and pressure control in the vacuum vessel 10 may be difficult. Therefore, in the above-described treatment device 1, by placing a dummy wafer on the stage 56, an amount of the first cooling gas supplied from the through hole 56a to a gap between the upper surface of the stage 56 and the lower surface of the dummy wafer is adjusted. As a result, operations such as loading or unloading the dummy wafer into or from the vacuum vessel 10 are required, resulting in problems of downgraded throughput.

In contrast, according to the second embodiment, the third cooling gas supply section 76, which is capable of supplying cooling gas to a gap between the upper surface of the stage 56 and the lower surface of the semiconductor wafer W, is provided separately from the first cooling gas supply section 54a which supplies cooling gas to a gap between the upper surface of the refrigerated heat transfer element 54 and the lower surface of the stage 56. Accordingly, the above-mentioned problems are solved.

### Third Embodiment

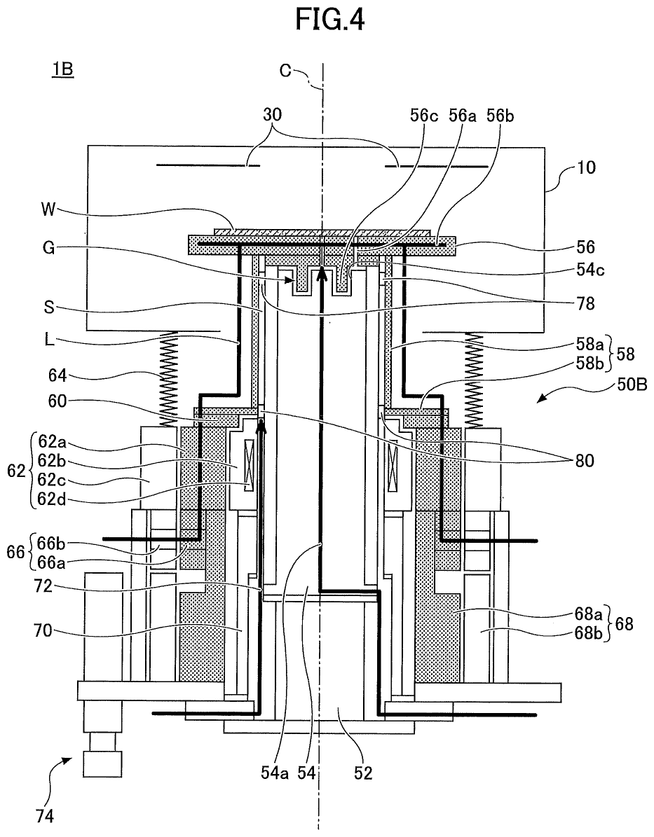

A treatment device having a placing table structure according to a third embodiment of the present invention will be described. In the third embodiment, a first sliding seal member 78 and a second sliding seal member 80 are further provided to the placing table structure 50 of the first embodiment. However, only one of the first sliding seal member 78 and the second sliding seal member 80 may be provided. Hereinafter, points different from the first embodiment will be mainly described. FIG. 4 is a schematic cross-sectional view illustrating an example of the treatment device according to the third embodiment.

The first sliding seal member 78 is disposed at an upper portion of the space S between the refrigerated heat transfer element 54 and the outer cylinder 58. In other words, the first sliding seal member 78 is provided around the recess 54c of the refrigerated heat transfer element 54 (or the protrusion 56c of the stage 56). Accordingly, the first sliding seal member 78 prevents the first cooling gas from leaking from the gap G to the space S, and thereby from entering the magnetic fluid seal section 62. The first sliding seal member 78 may be, for example, OmniSeal (registered trademark). The first sliding seal member 78 may be a gas separation structure using a magnetic fluid seal for example.

The second sliding seal member 80 is disposed at a lower portion of the space S between the refrigerated heat transfer element 54 and the outer cylinder 58. In other words, the second sliding seal member 80 is provided near the magnetic fluid seal section 62. This allows a cooling function of the second cooling gas to be isolated, and the second cooling gas can concentrate on a thermal insulation function between the magnetic fluid seal section 62 and the refrigerated heat transfer element 54.

According to a placing table structure 50B of the third embodiment described above, in addition to the aforementioned effects of the first embodiment, the following effects are achieved.

According to the third embodiment, sliding seal members (first sliding seal member 78 and second sliding seal member 80) are provided in the space S between the refrigerated heat transfer element 54 and the outer cylinder 58. Therefore, it is possible to prevent the first cooling gas from leaking from the gap G to the space S and from entering the magnetic fluid seal section 62.

Although the embodiments of the present invention are described above, the above descriptions are not intended to limit contents of the invention, and various modifications and enhancements can be made within the scope of the present invention.

In the above-described embodiments, a case in which the treatment device 1 is a film forming apparatus has been described, but the present invention is not limited thereto. For example, the treatment device 1 may be an etching apparatus.

This international application is based on and claims priority to Japanese Patent Application No. 2017-133991 filed on Jul. 7, 2017, and Japanese Patent Application No. 2018-039397 filed on Mar. 6, 2018, the entire contents of which are incorporated herein by reference.

### DESCRIPTION OF REFERENCE SYMBOLS

1 treatment device
10 vacuum vessel
30 target
50 placing table structure
52 refrigerator
54 refrigerated heat transfer element
54a first cooling gas supply section
54c recess
56 stage
56a through hole
56b chuck electrode
56c protrusion
58 outer cylinder
58a cylindrical portion
58b flange portion
60 heat insulating member
62 magnetic fluid seal section
62a rotating member
62b inner stationary member
62c outer stationary member
62d heating means
64 bellows
66 slip ring
66a rotor
66b stator
68 drive mechanism
68a rotor
68b stator
70 heat insulator
72 second cooling gas supply section
74 lifting mechanism
76 third cooling gas supply section
76a magnetic fluid seal section
76b cover
78 first sliding seal member
80 second sliding seal member
C central axis
L wiring
G gap
S space
W semiconductor wafer

1. A placing table structure comprising:
a refrigerated heat transfer element;
a refrigerator supporting the refrigerated heat transfer element, the refrigerator being configured to cool the refrigerated heat transfer element;
a rotatable outer cylinder disposed around the refrigerated heat transfer element; and
a stage connected to the outer cylinder, the stage being disposed above an upper surface of the refrigerated heat transfer element with inclusion of a gap between the refrigerated heat transfer element and the stage; wherein
the stage includes a protrusion protruding toward the refrigerated heat transfer element,
the refrigerated heat transfer element includes a recess fitted to the protrusion with the gap, and
at least one surface from among an outer surface of the protrusion and an inner surface of the recess is subjected to a roughening process.

2. (canceled)

3. The placing table structure according to claim 1, wherein the protrusion and the recess are of substantially annular shape surrounding a central axis of the stage.

4. The placing table structure according to claim 1, wherein the stage includes a plurality of protrusions, and the refrigerated heat transfer element includes a plurality of recesses.

5. (canceled)

6. The placing table structure according to claim 1, wherein the refrigerator is configured to cool the upper surface of the refrigerated heat transfer element to −30° C. or less.

7. The placing table structure according to claim 1, further comprising a heat insulator surrounding the refrigerator and the refrigerated heat transfer element, the heat insulator having a vacuum heat-insulating double-walled structure.

8. The placing table structure according to claim 1, wherein the gap is filled with a first cooling gas.

9. The placing table structure according to claim 8, wherein the refrigerated heat transfer element includes a first cooling gas supply section communicating with the gap, the first cooling gas supply section being configured to supply the first cooling gas to the gap.

10. The placing table structure according to claim 9, wherein the stage includes a through hole penetrating vertically, and the through hole communicates with the first cooling gas supply section via the gap.

11. The placing table structure according to claim 9, further comprising a second cooling gas supply section configured to supply a second cooling gas to a space between the refrigerated heat transfer element and the outer cylinder.

12. The placing table structure according to claim 9, further comprising a third cooling gas supply section configured to supply a third cooling gas to an upper surface of the stage.

13. The placing table structure according to claim 9, further comprising a sliding seal member provided in a space between the refrigerated heat transfer element and the outer cylinder, in order to prevent the first cooling gas from leaking via the space.

14. (canceled)

15. The placing table structure according to claim 1, wherein
the stage includes an electrostatic chuck, and
wiring configured to supply electric power to the electrostatic chuck is electrically connected to a power supply configured to supply the electric power to the wiring via a slip ring.

16. The placing table structure according to claim 1, wherein
the outer cylinder is rotatably supported via a magnetic fluid seal section, and
the magnetic fluid seal section includes a heating means.

17. A treatment device comprising:
the placing table structure according to claim 1; and
a target disposed above the stage.

18. The treatment device according to claim 17, further comprising a lifting mechanism configured to raise or lower an entirety of the placing table structure.

19. The placing table structure according to claim 11, wherein thermal conductivity of the second cooling gas is lower than thermal conductivity of the first cooling gas.

20. The placing table structure according to claim 11, wherein supply pressure of the second cooling gas is equal to or greater than supply pressure of the first cooling gas.
